(19) United States
(12) Patent Application Publication
(10) Pub. No.: US 2004/0161902 A1
(43) Pub. Date: Aug. 19, 2004

(54) Method for fabricating transistor of semiconductor device

(75) Inventor: Jeong Ho Park, Gyeonggi-do (KR)

Correspondence Address: PILLSBURY WINTHROP, LLP, P.O. BOX 10500, MCLEAN, VA, 22102, US

(73) Assignee: Dongbu Electronics Co., Ltd., Seoul (KR)

(21) Appl. No.: 10/746,142

(22) Filed: Dec. 29, 2003

(30) Foreign Application Priority Data
Dec. 31, 2002 (KR) 10-2002-0088275

(51) Int. Cl. H01L 21/336; H01L 21/4763

(52) U.S. Cl. 438/305; 438/589

(57) ABSTRACT

A method of fabricating a transistor with pin structure is disclosed. The disclosed method comprises the steps of forming a first pattern by removing some part of a substrate through an etching process; implanting ions to adjust threshold voltage into the first pattern; forming a groove by removing some part of the first pattern through an etching process; forming a gate insulating layer and a gate electrode in sequence, the gate insulating layer and the gate electrode filling up the groove; performing an ion implantation process using the gate electrode as a mask to form an LDD region in the first pattern; forming spacers on the sidewalls of the gate electrode; and performing an ion implantation process using the spacers and the gate electrode as a mask to form a source/drain region in the first pattern. The present invention can simplify the fabricating process of a transistor and reduce manufacturing costs compared to the process using a SOI wafer.

### BACKGROUND OF THE INVENTION

1. Field of the Invention

The present invention relates to a method for fabricating a transistor of a semiconductor device and, more particularly, to a method for fabricating a transistor with pin structure on the top of a substrate.

2. Background of the Related Art

Most semiconductor devices comprise transistors. The transistors have various shapes according to structures thereof. An example of such a transistor is a transistor with pin structure. In the pin transistor, transistor structures, i.e., a gate electrode and a source/drain region are placed on the top of the substrate. In fabricating a pin transistor, a lower conducting layer to form a gate electrode is defined vertically and, then, a gate insulating layer is formed along with the surface of the lower conducting layer formed vertically.

However, a conventional fabrication method of the pin transistor may complicate the process and increase manufacturing costs because the pin transistor is formed on a SOI (silicon-on insulator) wafer.

### SUMMARY OF THE INVENTION

Accordingly, the present invention is directed to a method for fabricating a transistor of a semiconductor device that substantially obviates one or more problems due to limitations and disadvantages of the related art.

An object of the present invention is to provide a method for fabricating a pin transistor by employing a simple process at a low cost.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, the present invention provides a method for fabricating a transistor of a semiconductor device, comprising the steps of:

forming a first pattern by removing some part of a substrate through an etching process;

implanting ions into the first pattern to adjust threshold voltage;

forming a groove by removing some part of the first pattern through an etching process;

forming a gate insulating layer and a gate electrode in sequence, the gate insulating layer and the gate electrode filling up the groove;

performing an ion implantation process using the gate electrode as a mask to form an LDD region in the first pattern;

forming spacers on the sidewalls of the gate electrode; and

performing an ion implantation process using the spacers and the gate electrode as a mask to form a source/drain region in the first pattern.

Here, the gate electrode is preferably formed of one selected from a group consisting of polysilicon, TiN, Ti/TiN, and WₓN_{y}. The gate insulating layer is formed through chemical vapor deposition, physical vapor deposition, or atomic layer deposition processes. The spacers are preferably a silicon nitride layer, an oxide layer, or a multi-layer consisting of oxide and silicon nitride.

Therefore, this invention can simplify the fabricating process of a pin transistor by forming a first pattern in some part of a substrate and forming a gate electrode and a source/drain region in the first pattern instead of using a SOI wafer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIGS. 1a through 1d illustrate, in cross-sectional views, the fabricating process of a transistor according to the present invention;

FIG. 2 is a top view of a pin transistor according to the present invention;

FIG. 3 is a cross-sectional view of FIG. 2 taken along a line A-A′; and

FIG. 4 is a cross-sectional view of FIG. 2 taken along a line B-B′.

### DETAILED DESCRIPTION OF THE PREFERRED EMBODIMENT

Reference will now be made in detail to the preferred embodiments of the present invention, examples of which are illustrated in the accompanying drawings.

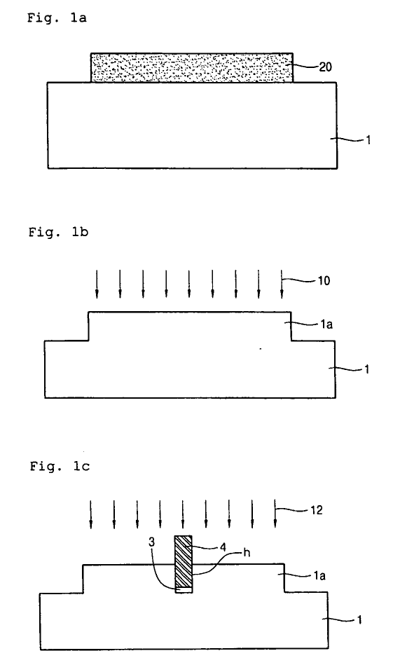

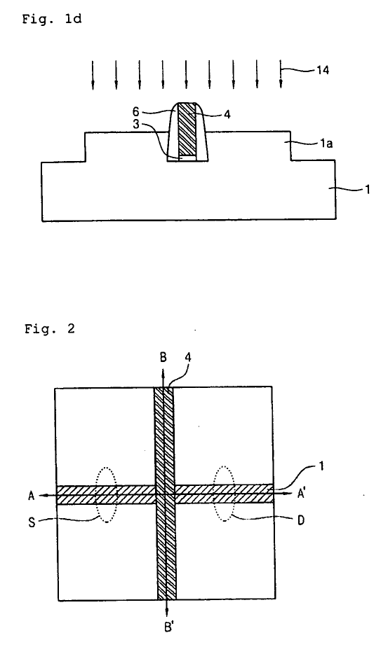

Referring to FIG. 1a, a first photoresist pattern 20 is formed on a substrate 1.

Referring to FIG. 1b, a dry etching process is applied to the substrate 1 using the first photoresist pattern 20 as a mask to form a first pattern 1a. The first photoresist pattern 20 is removed. Then, a first ion implantation process is performed to implant ions for adjustment of threshold voltage into the first pattern 1a. The first pattern 1a is a region in which a source/drain region is formed in a following process and, thus, the ions to adjust threshold voltage have to be implanted into the first pattern 1a.

Referring to FIG. 1c, a second photoresist pattern (not shown) is formed over the substrate 1 including the first pattern 1a. The second photoresist pattern defines a region for a gate electrode. An etching process is performed using the second photoresist pattern as a mask to form a groove h in the first pattern. Next, a silicon oxide layer (not shown) and a conducting layer (not shown) are formed in sequence in the groove h, using the second photoresist pattern as a mask. The conducting layer, the silicon oxide layer, and the second photoresist pattern positioned on the first pattern 1a are removed. As a result, a gate insulating layer 3 and a gate electrode 4 are formed in the groove h. The gate electrode 4 is preferably formed of one selected from a group consisting of polysilicon, TiN, Ti/TiN, and WₓN_{y}. In addition, the silicon oxide layer is preferably formed through chemical vapor deposition, physical vapor deposition, or atomic layer deposition processes.

Next, a second ion implantation process 12 is performed using the gate electrode 4 as a mask to form an LDD (lightly doped drain) region. As a result, an LDD region (not shown) with low concentration is formed in the region of the first pattern 1a except the gate electrode 4 region.

Referring to FIG. 1d, a thin layer is formed over the substrate including the gate electrode 4 and an etch back process is applied to the thin layer to form spacers 6 on the sidewalls of the gate electrode 4. The spacers 6 are preferably an oxide layer, a silicon nitride layer, or a multi-layer consisting of oxide and silicon nitride.

Then, a third ion implantation process 14 is performed using the spacers 6 and the gate electrode 4 as a mask to form a source/drain region. As a result, a source/drain region (not shown) is formed in the region of the first pattern 1a except the region for the gate electrode 4 and the spacers 6.

According to the foregoing process, a pin transistor is formed on a substrate.

FIG. 2 is a top view of a pin transistor according to an embodiment of this invention. A gate electrode 4 and a source/drain region S and D are formed in a first pattern 1a.

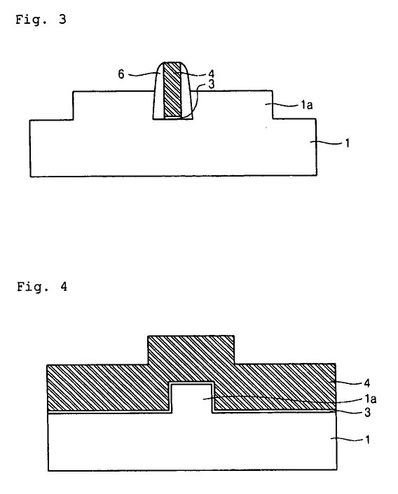

FIGS. 3 and 4 are cross-sectional views of FIG. 2 taken along lines A-A′ and B-B′, respectively. Particularly, FIG. 3 shows clearly the first pattern 1a and the gate insulating layer 3 formed on the first pattern 1a.

Accordingly, the present invention can simplify the fabricating process of a transistor and reduce manufacturing costs compared to the process using a SOI wafer.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method for fabricating a transistor of a semiconductor device comprising the steps of:
forming a first pattern by removing some part of a substrate;
implanting ions into the first pattern;
forming a groove by removing some part of the first pattern;
forming a gate insulating layer and a gate electrode, the gate insulating layer and the gate electrode filling up the groove;
performing an ion implantation using the gate electrode as a mask to form an LDD region in the first pattern;
forming spacers on the sidewalls of the gate electrode; and
performing an ion implantation process using the spacers and the gate electrode as a mask to form a source/drain region in the first pattern.

2. The method as defined by claim 1, wherein the gate electrode is formed of one selected from the group consisting of polysilicon, TiN, Ti/TiN, and WₓN_{y}.

3. The method as defined by claim 1, wherein the gate insulating layer is formed through chemical vapor deposition, physical vapor deposition, or atomic layer deposition processes.

4. The method as defined by claim 1, wherein the spacers are formed of a silicon nitride layer, an oxide layer, or a multi-layer consisting of oxide and silicon nitride.

5. The method as defined by claim 1, wherein the step of implanting ions into the first pattern is conducted to adjust threshold voltage.
